(19) United States
(12) Patent Application Publication
(10) Pub. No.: US 2024/0057349 A1
(43) Pub. Date: Feb. 15, 2024

(54) SEMICONDUCTOR PACKAGE STRUCTURE AND MANUFACTURING METHOD THEREOF

(71) Applicant: CHANGXIN MEMORY TECHNOLOGIES, INC., Hefei City (CN)

(72) Inventors: LING-YI CHUANG, Hefei (CN); Kaimin Lv, Hefei (CN)

(21) Appl. No.: 18/152,191

(22) Filed: Jan. 10, 2023

(30) Foreign Application Priority Data
Aug. 10, 2022 (CN) 202210957064.5

(51) Int. Cl. H10B 80/00; H01L 23/522; H01L 25/04; H01L 23/48; H01L 23/00

(52) U.S. Cl. CPC H10B 80/00; H01L 23/5226; H01L 25/04; H01L 23/481; H01L 24/11; H01L 24/14; H01L 24/17; H01L 2924/1436; H01L 2224/14135; H01L 2224/17135

(57) ABSTRACT

A semiconductor package structure and a manufacturing method thereof are provided. The semiconductor package structure includes a first semiconductor die and a second semiconductor die stack structure. A first wireless communication portion is formed in the first semiconductor die. The second semiconductor die stack structure includes a first die stack structure and a second die stack structure. A second wireless communication portion and a third wireless communication portion are respectively formed in two sides, along a second direction, of the first die stack structure. A fourth wireless communication portion is formed in one side, opposite to the first die stack structure, of the second die stack structure. The first direction is a direction parallel to a plane of the first semiconductor die, and the second direction is a direction perpendicular to the plane of the first semiconductor die.

### CROSS-REFERENCE TO RELATED APPLICATION

The disclosure is filed based upon and claims priority to Chinese patent application No. 202210957064.5, filed on Aug. 10, 2022 and entitled “SEMICONDUCTOR PACKAGE STRUCTURE AND MANUFACTURING METHOD THEREOF”, the disclosure of which is hereby incorporated by reference in its entirety.

### BACKGROUND

High Bandwidth Memory (HBM) is a kind of high-performance Dynamic Random Access Memory (DRAM) based on three-dimensional (3D) stack technology. Compared with traditional memory technology, HBM memory has higher bandwidth, more I/O quantity, lower power consumption and smaller size, and can be applied to high-performance computation, supercomputers, large data centers, artificial intelligence/deep learning, cloud computation and other fields.

HBM technology is mainly developed based on the demand for processor computation scale. In the early days, people had low requirement for computer data processing, the number of layers of processor architecture model is relatively small, the computation scale is relatively small and computing capability is relatively low. Later, with the development of Artificial Intelligence (AI) and other technologies, the requirement for processor becomes higher and higher, and the demand for computing capability increases correspondingly with the deepened model, which lead to the bandwidth bottleneck, that is, the I/O problem. At that time, it is solved by increasing the on-die cache and optimizing the scheduling model to increase the data reuse rate. However, with the popularization of AI and other technologies in the later period, the number of users is increased, and cloud AI processes expect multi-user, high throughput, low latency and high density deployment. The rapid increase of computing units makes the I/O bottleneck more and more serious. At this time, the appearance of on-die HBM makes it possible for AI/deep learning to be completely put on the die. While the integration level is improved, the bandwidth is no longer limited by the interconnection number of die pins, thus solving the bottleneck of bandwidth and computing capability to a certain extent. However, with the increasing of integration requirements of HBM, the number of die stack layers is increasing, and there are more and more technical difficulties.

### SUMMARY OF THE INVENTION

The present disclosure relates to the field of a three-dimensional manufacturing process technology, in particular to a semiconductor package structure and a manufacturing method thereof.

In view of this, the embodiments of the present disclosure provide a semiconductor package structure and a manufacturing method thereof.

According to a first aspect of the embodiments of the present disclosure, a semiconductor package structure is provided. The semiconductor package structure includes a first semiconductor die and a second semiconductor die stack structure.

A first wireless communication portion is formed in the first semiconductor die.

The second semiconductor die stack structure includes a first die stack structure located on the first semiconductor die and a second die stack structure located on the first die stack structure. The second semiconductor die stack structure includes a plurality of second semiconductor dies stacked in sequence along a first direction. A second wireless communication portion and a third wireless communication portion are respectively formed in two sides, along a second direction, of the first die stack structure. A fourth wireless communication portion is formed in one side, opposite to the first die stack structure, of the second die stack structure. The first direction is a direction parallel to a plane of the first semiconductor die, and the second direction is a direction perpendicular to the plane of the first semiconductor die.

The first wireless communication portion in the first semiconductor die is correspondingly disposed with the second wireless communication portion in the first die stack structure, and the third wireless communication portion in the first die stack structure is correspondingly disposed with the fourth wireless communication portion in the second die stack structure.

According to a second aspect of the embodiments of the present disclosure, a method for preparing a semiconductor package structure as described in any of the above embodiments is provided. The method includes the following operations.

A first die stack structure is formed. The first die stack structure includes a plurality of second semiconductor dies stacked in sequence along a first direction. A second wireless communication portion and a third wireless communication portion are formed in two sides, along a second direction, of the first die stack structure respectively.

A first semiconductor die is formed. A first wireless communication portion is formed in the first semiconductor die.

A surface, on which a second wireless communication portion is formed, of the first die stack structure is placed on the first semiconductor die.

A second die stack structure is formed. The second die stack structure includes a plurality of second semiconductor dies stacked in sequence along the first direction. A fourth wireless communication portion is formed in one side, along the second direction, of the second die stack structure.

A side surface, on which the fourth wireless communication portion is formed, of the second die stack structure is placed on the first die stack structure. The first direction is a direction parallel to a plane of the first semiconductor die, and the second direction is a direction perpendicular to the plane of the first semiconductor die.

The first wireless communication portion in the first semiconductor die is correspondingly disposed with the second wireless communication portion in the first die stack structure, and the third wireless communication portion in the first die stack structure is correspondingly disposed with the fourth wireless communication portion in the second die stack structure.

### BRIEF DESCRIPTION OF THE DRAWINGS

To more clearly explain the embodiments of the present disclosure or the technical solution in the conventional technology, the drawings required for use in the embodiments will be briefly described below. It is apparent that the drawings described below are only some of the embodiments of the present disclosure, from which other drawings may be obtained without any creative effort by a person of ordinary skill in the art.

FIG. 1 is a schematic diagram of structure of a semiconductor package structure provided by some embodiments of the present disclosure.

FIG. 2 is a schematic diagram of structure of a semiconductor package structure provided by some other embodiments of the present disclosure.

FIG. 3 is a top view of a first wireless communication portion provided by some embodiments of the present disclosure.

FIG. 4 is a schematic diagram of structure of a semiconductor package structure provided by yet some other embodiments of the present disclosure.

FIG. 5 is a side view, along a first direction, of a second conductive bump provided by some embodiments of the present disclosure.

FIG. 6 is a flow schematic diagram of a method for manufacturing the semiconductor package structure provided by some embodiments of the present disclosure.

FIG. 7A to FIG. 7H are schematic diagrams of device structures in the manufacturing process of the semiconductor package structure provided by some embodiments of the present disclosure.

### DETAILED DESCRIPTION

The following clearly describes the exemplary implementations disclosed by the embodiments of the disclosure with reference to the drawings. Although the drawings show exemplary implementations of the disclosure, it is to be understood that the disclosure may be implemented in various forms and shall not be limited by specific implementations described herein. On the contrary, providing these implementations is to understand the disclosure thoroughly, and the scope of the disclosure can be completely conveyed to technicians in the art.

A number of specific details are given below to provide a more thorough understanding of the disclosure. However, it is apparent to those skilled in the art that the disclosure may be implemented without one or more of these details. In other examples, to avoid confusion with the disclosure, some technical features known in the art are not described; namely, all the features of the actual embodiments are not described here, nor are known functions and structures described in detail.

In the drawings, dimensions of layers, areas, components and their relative dimensions may be exaggerated for clarity. The same drawing marks throughout represent the same components.

It is to be understood that description that an element or layer is “above”, “adjacent to”, “connected to”, or “coupled to” another element or layer may refer to that the element or layer is directly above, adjacent to, connected to or coupled to the other element or layer, or there may be an intermediate element or layer. On the contrary, description that an element is “directly on”, “directly adjacent to”, “directly connected to” or “directly coupled to” another element or layer refers to that there is no intermediate element or layer. It is to be understood that, although various elements, components, regions, layers and/or parts may be described with terms first, second, third, etc., these elements, components, regions, layers and/or parts should not be limited to these terms. These terms are used only to distinguish one element, component, region, layer or part from another element, component, region, layer or part. Therefore, a first element, component, region, layer or part discussed below may be represented as a second element, component, region, layer or part without departing from the teaching of the disclosure. However, when discussing a second element, component, region, layer or part, it does not necessarily imply the existence of a first element, component, region, layer or part of the disclosure.

Spatially relational terms such as “below”, “under”, “lower”, “beneath”, “above”, and “upper” may be used herein for convenience of description to describe a relationship between one element or feature and another element or feature illustrated in the drawings. It is to be understood that, in addition to the orientation shown in the figures, the spatially relational terms are intended to further include different orientations of devices in use and operation. For example, if the devices in the figures are turned over, elements or features described as being “under” or “beneath” or “below” other elements or features will be oriented to be “on” the other elements or features. Therefore, the exemplary terms “under” and “below” may include both upper and lower. The device may be otherwise oriented (rotated by 90 degrees or in other orientations) and the spatial descriptors used herein may be interpreted accordingly.

The terms used herein are for the purpose of describing specific embodiments only and not intended to limit the disclosure. As used herein, singular forms “a/an”, “one”, and “the” are also intended to include the plural forms, unless otherwise specified in the context. It is also to be understood that, when terms “composed of” and/or “including” are used in this specification, the presence of the features, integers, steps, operations, elements, and/or components is determined, but the presence or addition of one or more other features, integers, steps, operations, elements, components, and/or groups is also possible. As used herein, term “and/or” includes any and all combinations of the related listed items.

In order to thoroughly understand the disclosure, detailed steps and detailed structure will be presented in the following description to explain the technical solution of the disclosure. Optional embodiments of the disclosure are described in details below, however in addition to these detailed descriptions, and the disclosure may have other implementation modes.

The reference numbers of the drawings are described in the following: 10—First substrate, 11—Lead line, 12—Substrate connecting bump, 101—Groove, 20—First semiconductor die, 21—First conductive bump, 22—First wireless communication portion, 221—First sub-portion, 301—First die stack structure, 302—Second die stack structure, 300—Second semiconductor die stack body, 31—Second semiconductor die, 311—Through Silicon Via, 312—Fourth conductive bump, 32—Second conductive bump, 321—First sub-conductive bump, 322—Second sub-conductive bump, 33—Second wireless communication portion, 331—Second sub-portion, 34—Third wireless communication portion, 341—Third sub-portion, 35—Fourth wireless communication portion, 351—Fourth sub-portion, 40—Second substrate, 41—Signal line, 411—Ground line, 412—Power line, 42—Third conductive bump, 40′—Remaining second substrate, 50—Adhesive film, 60—Dielectric layer, 70—Filling layer, and 80—Package compound structure.

HBM technology is the main representative product of DRAM in the development from traditional two-dimensional (2D) to stereo 3D, which starts the way of DRAM 3D. In the HBM, the dies are stacked by Through Silicon Via (TVS) technology to increase throughput and overcome the limitation of bandwidth in a single package, and several DRAM nude dies are stacked vertically, and nude dies are connected by using TVS technology. From a technology view, HBM makes full use of space and reduces area, which is in line with the development trend of miniaturization and integration in semiconductor industry, and breaks through the bottleneck of memory capacity and bandwidth, so that it is regarded as a new generation DRAM solution.

In the package of 3D IC products, DRAM dies are generally stacked on Logic die in a parallel stack (P-Stack) way. With the increasing of integration requirements, the number of DRAM die stack layers is increasing, and there are more and more technical difficulties. For example, the communication distance between DRAM dies stacked at the upper and logic die at the lower is getting longer and longer, the communication delays between DRAM dies at different layers and logic die will be different due to different distances, TSV for communication will increase proportionally, and wafer area is sacrificed.

In the embodiments of the present disclosure, wireless communication portions are formed in both the first semiconductor die and the second semiconductor die stack structure, so that wireless communication is performed between the first semiconductor die and the first die stack structure through a first wireless communication portion and a second wireless communication portion and wireless communication is performed between the first die stack structure and the second die stack structure through the third wireless communication portion and the fourth wireless communication portion. In this way, the second semiconductor die stack structure stacked vertically performs wireless communication in such a way, and the problem that the communication delays between the upper and lower die stack structures and the first semiconductor die are different due to the difference in distance can be solved.

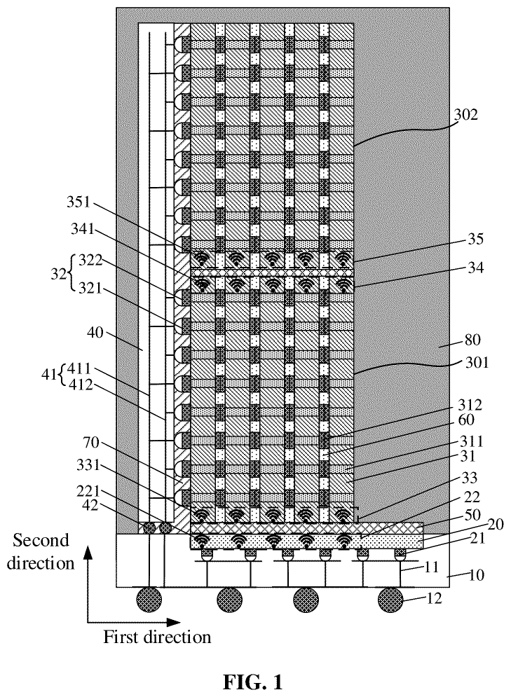

Some embodiments of the present disclosure provide a semiconductor package structure. FIG. 1 is a schematic diagram of structure of a semiconductor package structure provided by some embodiments of the present disclosure.

Referring to FIG. 1, the semiconductor package structure includes a first semiconductor die 20 and a second semiconductor die stack structure.

A first wireless communication portion 22 is formed in the first semiconductor die 20.

The second semiconductor die stack structure includes a first die stack structure 301 located on the first semiconductor die 20 and a second die stack structure 302 located on the first die stack structure 301. The second semiconductor die stack structure includes a plurality of second semiconductor dies 31 stacked in sequence along a first direction. A second wireless communication portion 33 and a third wireless communication portion 34 are respectively formed in two sides, along a second direction, of the first die stack structure 301. A fourth wireless communication portion 35 is formed in one side, opposite to the first die stack structure 301, of the second die stack structure 302. The first direction is a direction parallel to a plane of the first semiconductor die 20, and the second direction is a direction perpendicular to the plane of the first semiconductor die 20.

The first wireless communication portion 22 in the first semiconductor die 20 is correspondingly disposed with the second wireless communication portion 33 in the first die stack structure 301, and the third wireless communication portion 34 in the first die stack structure 301 is correspondingly disposed with the fourth wireless communication portion 35 in the second die stack structure 302.

In some embodiments of the present disclosure, wireless communication portions are formed in both the first semiconductor die and the second semiconductor die stack structure, so that wireless communication is performed between the first semiconductor die and the first die stack structure through a first wireless communication portion and a second wireless communication portion and wireless communication is performed between the first die stack structure and the second die stack structure through the third wireless communication portion and the fourth wireless communication portion. In this way, the second semiconductor die stack structure stacked vertically performs wireless communication in such a way, and the problem that the communication delays between the upper and lower die stack structures and the first semiconductor die are different due to the difference in distance can be solved.

In some embodiments, a plurality of second conductive bumps 32 are formed in one side along the first direction of the second semiconductor die stack structure

The semiconductor package structure further includes a first substrate 10 and a second substrate 40.

The first semiconductor die 20 is connected with the first substrate 10 through a first conductive bump 21.

A signal line 41 in the second substrate 40 is connected with the plurality of second conductive bumps 32. A third conductive bump 42 is formed on one side, close to the first substrate 10, of the second substrate 40, along the second direction, and the second substrate 40 is connected with the first substrate 10 through the third conductive bump 42.

In some embodiments, the first substrate 10 may be a printed circuit board (PCB) or a redistributed substrate.

The first substrate 10 may include a first base (not shown) and a first upper insulating dielectric layer and a first lower insulating dielectric layer (not shown) on an upper surface and a lower surface of the first base, respectively.

The first base may be a silicon substrate, a germanium substrate, a silicon germanium substrate, a silicon carbide substrate, a Silicon On Insulator (SOI) substrate, a Germanium On Insulator (GOI) substrate, or the like. It may also be a substrate including other element semiconductors or compound semiconductors, such as a glass substrate or a Group III-V compound substrate (such as a gallium nitride substrate or a gallium arsenide substrate, etc.). It may also be a stack structure, such as Si/SiGe, etc., and other epitaxial structures, such as silicon-Germanium On Insulator (SGOI), etc.

The first upper insulating dielectric layer and the first lower insulating dielectric layer may be solder resist layers. For example, the materials of the first upper insulating dielectric layer and the first lower insulating dielectric layer may be green paint.

A substrate connecting bump 12 is formed on the lower surface of the first substrate 10. The semiconductor package structure may be electrically connected with an external device through the substrate connecting bump 12. At least one of a control signal, a power signal, and a ground signal for operating the first semiconductor die and the second semiconductor die may be received from the external device. Alternatively, data signals to be stored in the first semiconductor die and the second semiconductor die may be received from the external device, or data in the first semiconductor die and the second semiconductor die may be supplied to the external device.

The substrate connecting bump 12 includes a conductive material. In some embodiments of the present disclosure, the substrate connecting bump 12 is a solder ball. It is understood that the shape of the substrate connecting bump provided in some embodiments of the present disclosure is only a specific and feasible embodiment in the embodiment of the present disclosure, and does not constitute a limitation to the present disclosure. The substrate connecting bump may also be in other shape structures. The number, space and location of the substrate connecting bumps are not limited to any particular arrangement and various modifications may be made.

In some embodiments, a first conductive bump 21 is formed on one surface of the first semiconductor die 20.

The material of the first conductive bump 21 may include at least one of aluminum, copper, nickel, tungsten, platinum, and gold.

The first semiconductor die 20 and the first substrate 10 are electrically connected through the first conductive bump 21. The power is supplied to the first semiconductor die by the first substrate 10 in a wired manner, and signal exchange is performed, thus having high reliability.

The first conductive bump 21 is further connected with the substrate connecting bump 12 through the lead line 11 in the first substrate 10, so that the first semiconductor die 20 may exchange information with an external device through the substrate connecting bump 12.

In some embodiments, as shown in FIG. 1, a groove 101 is formed in the first substrate 10, and the first semiconductor die 20 is located in the groove 101.

In some embodiments, the first semiconductor die is placed in the groove of the first substrate, so that the package height of the semiconductor package structure can be reduced.

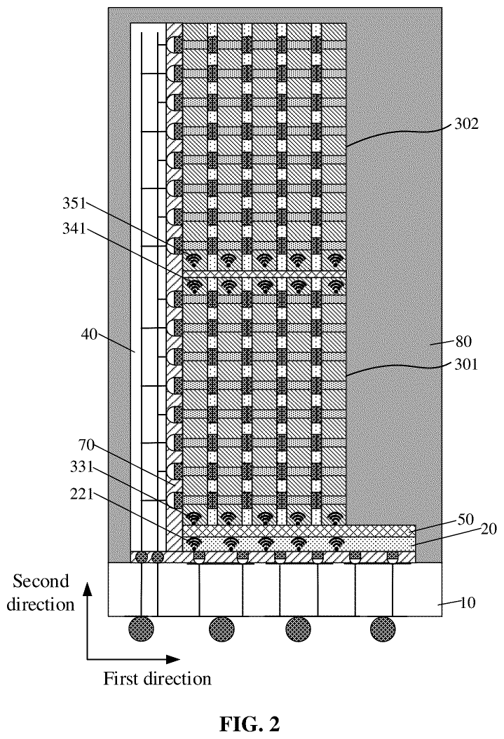

In some other embodiments, as shown in FIG. 2, the first semiconductor die 20 is located on the first substrate 10, and the first conductive bump 21 is located between the first semiconductor die 20 and the first substrate 10.

In some embodiments, the first semiconductor die is located on the first substrate, so that the first substrate does not need to be provided with the groove. Therefore, the process is simpler, and there is a gap between the first semiconductor die and the first substrate, which can increase the heat dissipation effect of the first semiconductor die.

The stack number of the second semiconductor dies 31 in the second semiconductor die stack structure may be a plurality. In the embodiment of the present disclosure, as shown in FIG. 1, the stack number of the second semiconductor dies 31 in the second semiconductor die stack structure is five.

In some embodiments, the first semiconductor die 20 includes a logic die and the second semiconductor die stack structure includes a DRAM die.

In some embodiments, the semiconductor package structure further includes an adhesive film 50 located between the first semiconductor die 20 and the second semiconductor die stack structure.

In some embodiments, the first die stack structure 301 and the second die stack structure 302 are bonded by the adhesive film 50.

The first semiconductor die 20 and the second semiconductor die stack structure can be bonded through the adhesive film 50, so as to enhance the adhesion between them, thereby improving the firmness of the semiconductor package structure. Meanwhile, the adhesive film may adjust the distance between the second semiconductor die stack structure and the first semiconductor die. That is, it is avoided that there is an angle in the bonding between the second substrate and the second conductive block, which causes additional stress, and the second conductive block on the second semiconductor die stack structure is damaged.

In some embodiments, the adhesive film 50 includes a crystal fixing adhesive film.

In some embodiments, the adhesive film includes a first adhesive film and a second adhesive film (not shown) located on the first adhesive film, and the elastic modulus of the second adhesive film is greater than the elastic modulus of the first adhesive film.

In some embodiments of the present disclosure, because the first adhesive film is connected with the first semiconductor die, which mainly plays the role of bonding. The second adhesive film is connected with the second semiconductor die stack structure, which mainly plays a role of preventing the die from warping. Because the elastic modulus of the second adhesive film is higher, warping will not occur in the packaging process. The elastic modulus of the first adhesive film is lower, which will not affect the bonding force between the first semiconductor die and the second semiconductor die stack structure in the subsequent process.

In some embodiments of the present disclosure, a plurality of second semiconductor dies in the second semiconductor die stack structure are vertically stacked (V-Stack) side by side on the first semiconductor die. In this way, the first semiconductor die and the second semiconductor die can communicate in a wireless manner, which can effectively solve the communication difficulty caused by the increase of the stack layer number of of the second semiconductor die when a plurality of second semiconductor dies are stacked in parallel (P-Stack) in sequence on the first semiconductor die.

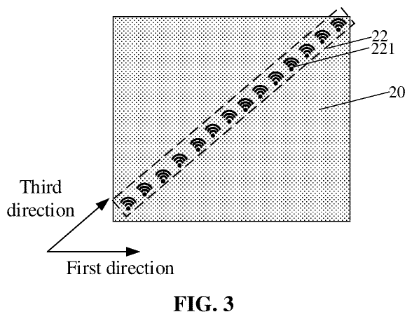

FIG. 3 is a top view of the first wireless communication portion provided by some embodiments of the present disclosure.

In some embodiments, as shown in FIG. 3, the first wireless communication portion 22 includes a plurality of first sub-portions 221, first sub-portions 221 of the plurality of first sub-portions 221 are disposed along a third direction in the first semiconductor die 20. The third direction is a direction parallel to the plane of the first semiconductor die 20 and forms an included angle with the first direction, and the included angle is greater than 25° and less than 65°.

In some embodiments, the first wireless communication portion is disposed by using this included angle, which can increase the distances between the various first sub-portions, thereby reducing mutual interference. Because the second communication portion is disposed correspondingly with the first communication portion, the second wireless communication portion is also disposed at this included angle, which also increases the distances between the various second sub-portions in the second wireless communication portion.

In some embodiments, the second wireless communication portion 33 includes a plurality of second sub-portions 331, the third wireless communication portion 34 includes a plurality of third sub-portions 341, and the fourth wireless communication portion 35 includes a plurality of fourth sub-portions 351. At least one second sub-portion 331 and at least one third sub-portion 341 are included in each of second semiconductor dies 31 in the first die stack structure 301, and at least one fourth sub-portion 351 is included in each of second semiconductor dies 31 in the second die stack structure 302.

Specifically, the first sub-portions in the first semiconductor die correspond to the second sub-portions in the first die stack structure one by one, and the third sub-portions in the first die stack structure correspond to the fourth sub-portions in the second die stack structure one by one. As such, the first semiconductor die can communicate with the first die stack structure through the first sub-portion and the second sub-portion. Then the first die stack structure transmits data to the third sub-portion through internal lines, and then the first die stack structure communicates with the second die stack structure through the third sub-portion and the fourth sub-portion, thereby solving the problem that the communication delays between the upper and lower die stack structures and the first semiconductor die are different due to different distances.

In some embodiments, the second semiconductor die stack structure includes N first die stack structures 301 stacked along the second direction. N is an integer greater than or equal to 1.

In some embodiments, as shown in FIG. 1 and FIG. 2, the number of the first die stack structure 301 is 1.

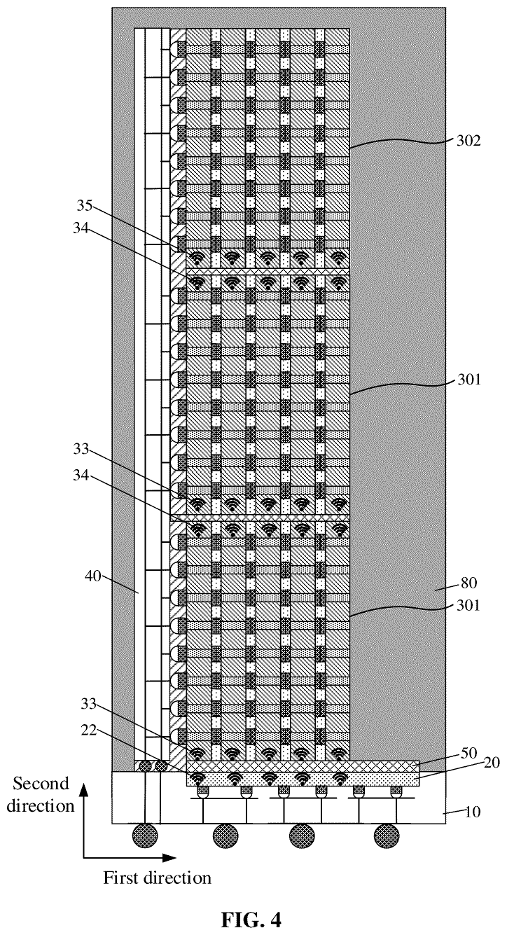

In some other embodiments, the number of the first die stack structures 301 is a plurality. Specifically, as shown in FIG. 4, the number of the first die stack structures 301 is 2. In this embodiment, the second communication portion 33 in the first die stack structure 301 at the lower layer is disposed correspondingly with the first communication portion 22. The third communication portion 34 in the first die stack structure 301 at the lower layer is disposed correspondingly with the second communication portion 33 in the first die stack structure 301 at the upper layer. The third communication portion 34 in the first die stack structure 301 at the upper layer is disposed correspondingly with the fourth communication portion 35 in the second die stack structure 302.

The capacity density of the second semiconductor die stack structure may also be increased by stacking the first die stack structure of a greater layer number along the second direction.

In some embodiments, as shown in FIG. 1, the semiconductor package structure further includes a plurality of Through Silicon Vias (TSVs) 311 and a plurality of fourth conductive bumps 312. The second semiconductor dies 31 are penetrated by the plurality of TSVs 311 along the first direction. The plurality of fourth conductive bumps 312 are located between two adjacent second semiconductor dies 31 and are connected with the TSVs 311 correspondingly.

The two adjacent second semiconductor dies in the second semiconductor die stack structure are electrically connected through the TSV and the fourth conductive block.

The second semiconductor die stack structure is obtained in a hybrid bonding manner, so that the stacked die structure can be taken as a whole, thereby improving the mechanical strength of vertical placement of the stack structure while reducing the pressure subjected by the die.

The semiconductor package structure further includes a dielectric layer 60 located between two adjacent second semiconductor dies 31. The two adjacent second semiconductor dies can be insulated and isolated by disposing the dielectric layer, and the fourth conductive bump is located in the dielectric layer, so that the possibility of coupling between the adjacent fourth conductive bumps can be reduced.

The material of the dielectric layer 60 includes an oxide. In a specific embodiment, the material of the dielectric layer 60 includes SiO2.

In addition, in order to increase the thickness of the second semiconductor die stack structure and further enhance its mechanical strength, it is not necessary to thin the outermost die during the processing process of TSVs.

The material and structure of the second substrate 40 may be the same as that of the first substrate 10. Elaborations are omitted herein.

In some embodiments, the signal line 41 includes a ground line 411 and a power line 412, and the second conductive bumps 32 include first sub-conductive bumps 321 and second sub-conductive bumps 322. The ground line 411 is electrically connected with the first sub-conductive bump 321, and the power line 412 is electrically connected with the second sub-conductive bump 322.

In some embodiments, the ground signal of the second semiconductor die stack structure is led out to the ground line 411 through the first sub-conductive bump 321. The power signal of the second semiconductor die stack structure is led out to the power line 412 through the second sub-conductive bump 322. Then the ground line 411 and the power line 412 are electrically connected with the first substrate 10 through the third conductive bump 42. Therefore, the first substrate 10 supplies power to the second semiconductor die stack structure through the third conductive bump 42, the ground line 411 and the power line 412.

The third conductive bump 42 is further connected with the substrate connecting bump 12 through the lead line 11 in the first substrate 10, so that the second semiconductor die stack structure can exchange information with the external device through the substrate connecting bump 12.

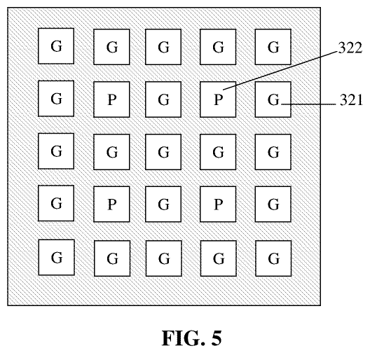

FIG. 5 is a side view along the first direction of the second conductive bump provided by some embodiments of the present disclosure.

As shown in FIG. 5, two adjacent second sub-conductive bumps 322 are at least spaced by one first sub-conductive bump 321, and the second sub-conductive bumps 322 are surrounded by first sub-conductive bumps 321.

P (Power) in the FIG. 5 represents the second sub-conductive bump 322 and G (Ground) in the FIG. 5 represents the first sub-conductive bump 321.

The second sub-conductive bumps 322 are completely surrounded by first sub-conductive bumps 321, and since the first sub-conductive bumps 321 are connected with the ground signal and the second sub-conductive bump 322 is connected with the power signal, crosstalk between different power signals can be reduced and shielding of the power supply can be enhanced.

In some embodiments, the semiconductor package structure further includes a package compound structure 80 located on the first substrate 10. The package compound structure 80 at least wraps the second semiconductor die stack structure and the second substrate 40.

In some embodiments shown in FIG. 2, the package compound structure 80 further wraps the first semiconductor die 20.

The package compound structure 80 includes a silicon-containing compound. The silicon-containing compound may be a spin on glass coating (SOG), a silicon-containing Spin on Dielectric (SOD), or other silicon-containing spin coating material.

The package compound structure 80 is formed and the material of the package compound structure 80 includes a silicon-containing compound, so that the warping problem of the second semiconductor die stack structure can be reduced.

In some embodiments, the semiconductor package structure further includes a filling layer 70. The filling layer 70 is located between the second semiconductor die stack structure and the second substrate 40, and/or, located between the first semiconductor die 20 and the first substrate 10.

In some embodiments, the filling layer 70 may further be located between the second substrate 40 and the first substrate 10.

For example, in an embodiment, as shown in FIG. 1, when the first semiconductor die 20 is located in a groove of the first substrate 10, the filling layer 70 may be located between the second semiconductor die stack structure and the second substrate 40, and/or, located between the second substrate 40 and the first substrate 10.

In some other embodiments, as shown in FIG. 2, when the first semiconductor die 20 is located above the first substrate 10, the filling layer 70 may be located between the first semiconductor die 20 and the first substrate 10, and/or, located between the second semiconductor die stack structure and the second substrate 40, and/or, located between the second substrate 40 and the first substrate 10.

For a 3D stacked second semiconductor die stack structure, the warping degree of the second semiconductor die stack structure is high because the thickness along the first direction is thin. When the second semiconductor die stack structure is erected on the first semiconductor die, it is difficult to weld between the second semiconductor die stack structure and the second substrate because of the high warping degree. Therefore, a filling layer is provided between the second semiconductor die stack structure and the second substrate, and between the first substrate and the first semiconductor die, which can effectively reduce the impact caused by the mismatch of the overall temperature expansion characteristics between the die and the substrate or the external force, and increase the reliability of the semiconductor package structure.

In some embodiments, the material of the filling layer 70 includes Epoxy.

Epoxy may be coated on the edge of the die by using capillary action principle, so that it can penetrate into the bottom of the die or substrate, and then be cured by heating. Because Epoxy can effectively improve the mechanical strength of solder joints, the service life of the die is prolonged.

In some embodiments, the Young's modulus of the filling layer 70 is greater than the Young's modulus of the package compound structure 80.

Young's modulus is a physical quantity that can describe the ability of solid materials to resist deformation. If the Young's modulus is greater, the ability to resist deformation is greater. When Young's modulus is too low, it will be difficult to maintain the rigidity of the package structure, and it is easy to cause issues such as deformation, warping or damage, etc. Therefore, in the embodiments of the present disclosure, the filling layer is formed and the Young's modulus of the filling layer is greater than the Young's modulus of the package compound structure, so that the filling layer can have sufficient strength to support the whole package structure, and thus the package structure is not prone to occur issues such as deformation, warping, damage and the like.

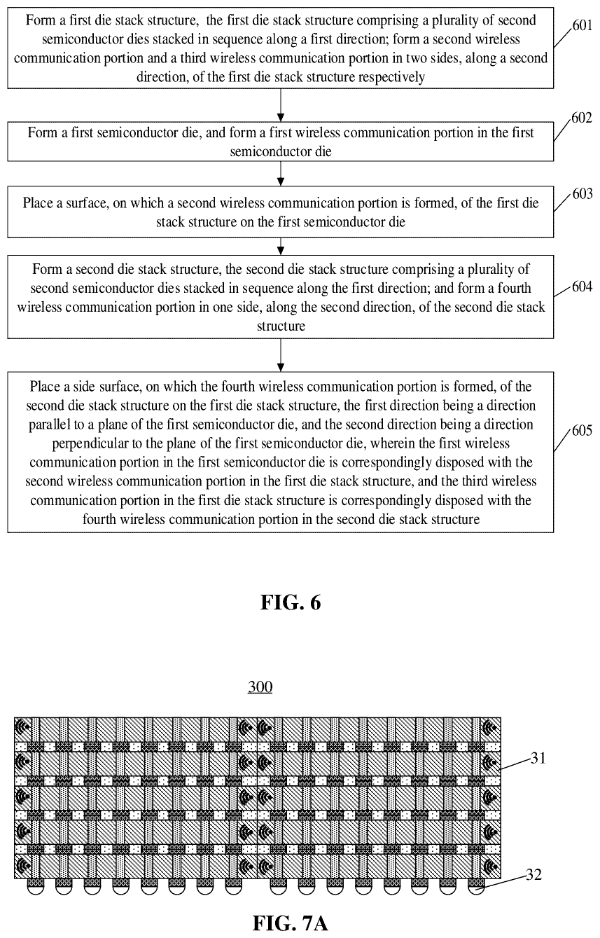

Some embodiments of the present disclosure further provide a method for manufacturing a semiconductor package structure as described in any of the above embodiments. The reference for the specific method is made to FIG. 6. As shown in FIG. 6, the method includes the following operations.

In operation 601, a first die stack structure is formed. The first die stack structure includes a plurality of second semiconductor dies stacked in sequence along a first direction. A second wireless communication portion and a third wireless communication portion are formed in two sides, along a second direction, of the first die stack structure respectively.

In operation 602, a first semiconductor die is formed, and a first wireless communication portion is formed in the first semiconductor die.

In operation 603, a surface, on which a second wireless communication portion is formed, of the first die stack structure is placed on the first semiconductor die.

In operation 604, a second die stack structure is formed, the second die stack structure includes a plurality of second semiconductor dies stacked in sequence along a first direction, and a fourth wireless communication portion is formed in one side, along the second direction, of the second die stack structure.

In operation 605, a side surface, on which the fourth wireless communication portion is formed, of the second die stack structure is placed on the first die stack structure. The first direction is a direction parallel to a plane of the first semiconductor die, and the second direction is a direction perpendicular to the plane of the first semiconductor die.

The first wireless communication portion in the first semiconductor die is correspondingly disposed with the second wireless communication portion in the first die stack structure, and the third wireless communication portion in the first die stack structure is correspondingly disposed with the fourth wireless communication portion in the second die stack structure.

The method for preparing a semiconductor package structure provided by the embodiments of the present disclosure will be described in further detail below in combination with specific embodiments.

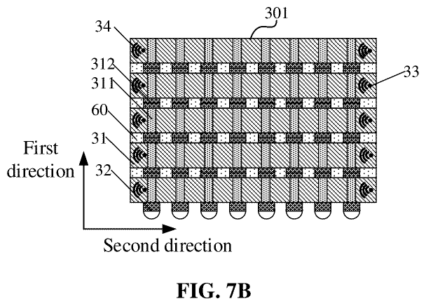

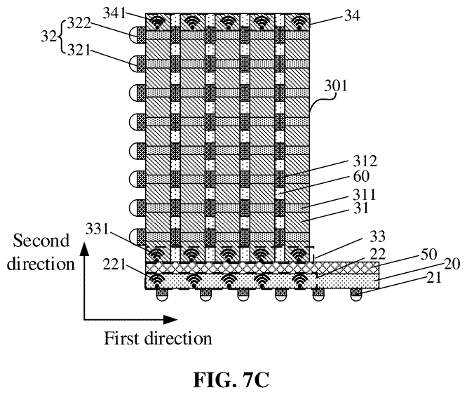

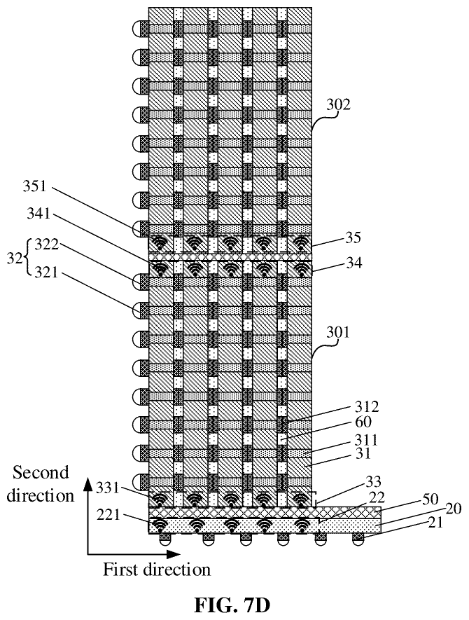

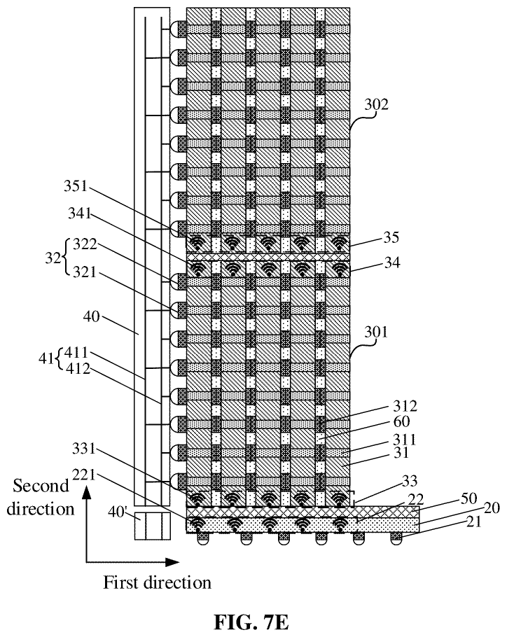

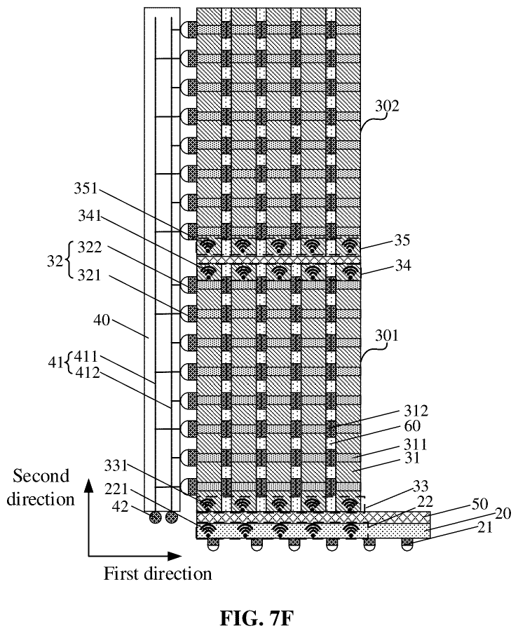

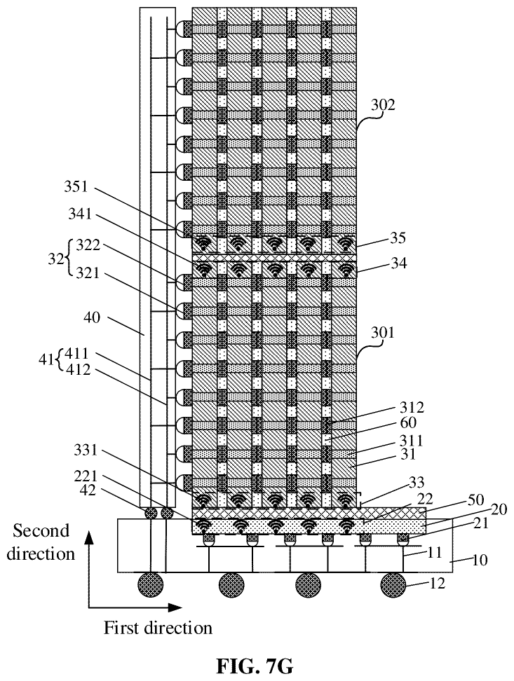

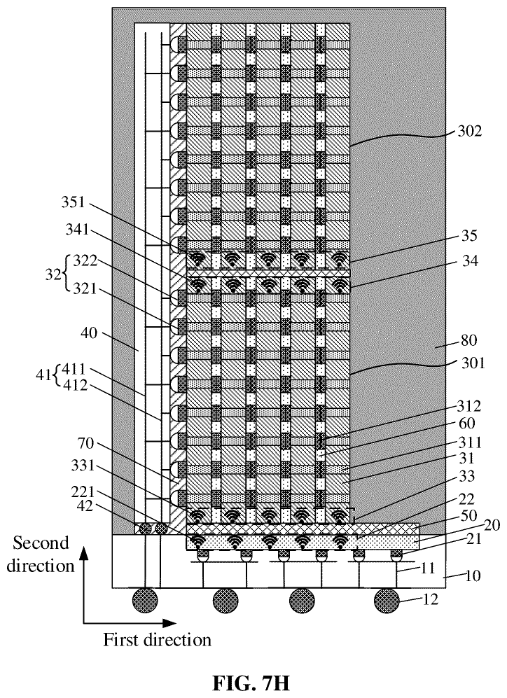

FIG. 7A to FIG. 7H are schematic diagrams of device structures in the manufacturing process of the semiconductor package structure provided by some embodiments of the present disclosure.

Firstly, referring to FIG. 7A and FIG. 7B, the first die stack structure 301 is formed. The first die stack structure 301 includes a plurality of second semiconductor dies 31 stacked in sequence along the first direction. A second wireless communication portion 33 and a third wireless communication portion 34 are respectively formed in two sides, along a second direction, of the first die stack structure 301.

Referring to FIG. 7A, the operation of forming the first die stack structure 301 includes the following operation. Second semiconductor dies 31 of a plurality of the second semiconductor dies 31 are connected by hybrid bonding to form a second semiconductor die stack body 300.

The second semiconductor die stack body 300 is cut to form a plurality of first die stack structures 301.

Referring to FIG. 7B, the method further includes the following operation. A plurality of TSVs 311 are formed. The second semiconductor dies 31 are penetrated by the plurality of TSVs along the stack direction.

A plurality of fourth conductive bumps 312 are formed between two adjacent second semiconductor dies 31, and the fourth conductive bumps 312 are connected with the TSVs 311 correspondingly.

Two adjacent second semiconductor dies in the first die stack structure are electrically connected through a fourth conductive block and the TSV.

The method for manufacturing a semiconductor package structure further includes the following operation. A dielectric layer 60 is formed between two adjacent second semiconductor dies 31. Two adjacent second semiconductor dies can be insulated and isolated by disposing the dielectric layer, and the fourth conductive bump is located in the dielectric layer, so that the possibility of coupling between the adjacent fourth conductive bumps can be reduced.

The material of the dielectric layer 60 includes an oxide. In a specific embodiment, the material of the dielectric layer 60 includes SiO2.

With continued reference to FIG. 7B, the second wireless communication portion 33 includes a plurality of second sub-portions 331 and the third wireless communication portion 34 includes a plurality of third sub-portions 341. At least one second sub-portion 331 and at least one third sub-portion 341 are included in each of second semiconductor dies 31 in the first die stack structure 301.

Next referring to FIG. 7C, operations 602 and 603 are performed, a first semiconductor die 20 is formed. A first wireless communication portion 22 is formed in the first semiconductor die 20. The surface, on which a second wireless communication portion 33 is formed, of the first die stack structure 301 is placed on the first semiconductor die 20.

In some embodiments, if the initial stack direction of the first die stack structure is a direction perpendicular to the plane of the first semiconductor die, the first die stack structure is rotated 90 degrees and placed on the first semiconductor die.

In other embodiments, if the initial stack direction of the first die stack structure is a direction parallel to the plane of the first semiconductor die, there is no need to rotate the first die stack structure.

In some embodiments, the method further includes the following operation. A first conductive bump 21 is formed on one side surface, away from the first die stack structure 301, of the first semiconductor die 20.

In actual operation, an adhesive film 50 is formed on the first semiconductor die 20. The first die stack structure 301 is connected with the first semiconductor die 20 through the adhesive film 50.

The first semiconductor die 20 and the first die stack structure 301 can be bonded through the adhesive film 50, so as to enhance the adhesion between them, thereby improving the firmness of the semiconductor package structure.

In some embodiments, the adhesive film 50 includes a crystal fixing adhesive film.

In some embodiments, the adhesive film includes a first adhesive film and a second adhesive film (not shown) located on the first adhesive film, and the elastic modulus of the second adhesive film is greater than the elastic modulus of the first adhesive film.

In some embodiments of the present disclosure, because the first adhesive film is connected with the first semiconductor die, it mainly plays the role of bonding. The second adhesive film is connected with the second semiconductor die stack structure, and it is mainly plays the role of preventing the die from warping. Because the elastic modulus of the second adhesive film is higher, warping will not occur in the packaging process. The elastic modulus of the first adhesive film is lower, which will not affect the bonding force between the first semiconductor die and the second semiconductor die stack structure in the subsequent process.

In some embodiments, as shown in FIG. 3, the first wireless communication portion 22 includes a plurality of first sub-portions 221, first sub-portions 221 of the plurality of first sub-portions 221 are disposed along a third direction in the first semiconductor die 20. The third direction is a direction parallel to the plane of the first semiconductor die 20 and forms an included angle with the first direction, and the included angle is greater than 25° and less than 65°.

In some embodiments, the first wireless communication portion is disposed at this included angle, and the distances between the various first sub-portions can be increased, thereby reducing mutual interference. Because then the second communication portion is disposed correspondingly with the first communication portion, the second wireless communication portion is also disposed at this included angle, which also increases the distances between the various second sub-portions in the second wireless communication portion.

In some embodiments, as shown in FIG. 7C, the number of the first die stack structure 301 is 1.

In other embodiments, the number of the first die stack structures 301 is a plurality. Specifically, as shown in FIG. 4, the number of the first die stack structures 301 is 2. In this embodiment, the second communication portion 33 in the first die stack structure 301 at the lower layer is disposed correspondingly with the first communication portion 22. The third communication portion 34 in the first die stack structure 301 at the lower layer is disposed correspondingly with the second communication portion 33 in the first die stack structure 301 at the upper layer. The third communication portion 34 in the first die stack structure 301 at the upper layer is disposed correspondingly with the fourth communication portion 35 in the second die stack structure 302.

Next referring to FIG. 7D, the operations 604 and 605 are performed. A second die stack structure 302 is formed. The second die stack structure 302 includes a plurality of second semiconductor dies 31 stacked in sequence along the first direction. A fourth wireless communication portion 35 is formed in one side along the second direction of the second die stack structure 302.

A side surface, on which the fourth wireless communication portion 35 is formed, of the second die stack structure 302 is placed on the first die stack structure 301. The first direction is a direction parallel to the plane of the first semiconductor die 20, and the second direction is a direction perpendicular to the plane of the first semiconductor die 20. The first wireless communication portion 22 in the first semiconductor die 20 is correspondingly disposed with the second wireless communication portion 33 in the first die stack structure 301, and the third wireless communication portion 34 in the first die stack structure 301 is correspondingly disposed with the fourth wireless communication portion 35 in the second die stack structure 302.

The formation process of the second die stack structure 302 is the same as that of the first die stack structure 301. Elaborations are omitted herein.

In some embodiments, if the initial stack direction of the second die stack structure is a direction perpendicular to the plane of the first semiconductor die, the first die stack structure, after being rotated 90 degrees, is placed on the first die stack structure.

In other embodiments, if the initial stack direction of the second die stack structure is a direction parallel to the plane of the first semiconductor die, there is no need to rotate the first die stack structure.

In actual operation, an adhesive film 50 is formed on the first die stack structure 301. The second die stack structure 302 is formed on the adhesive film 50. The first die stack structure 301 and the second die stack structure 302 are bonded through the adhesive film 50.

In some embodiments, the fourth wireless communication portion 35 includes a plurality of fourth sub-portions 351, and at least one fourth sub-portion 351 is included in each of second semiconductor dies 31 in the second die stack structure 302.

Specifically, the first sub-portions in the first semiconductor die correspond to the second sub-portions in the first die stack structure one by one, and the third sub-portions in the first die stack structure correspond to the fourth sub-portions in the second die stack structure one by one. As such, the first semiconductor die can communicate with the first die stack structure through the first sub-portion and the second sub-portion. Then the first die stack structure transmits data to the third sub-portion through internal lines, and then the first die stack structure communicates with the second die stack structure through the third sub-portion and the fourth sub-portion, thereby solving the problem that the communication delays between the upper and lower die stack structures and the first semiconductor die are different due to different distances.

In some embodiments, the method further includes the following operations. A plurality of second conductive bumps 32 are formed on one side, along the first direction, of the first die stack structure 301 and the second die stack structure 302.

Next referring to FIG. 7E and FIG. 7F, the method further includes the following operations. A second substrate 40 is provided after forming a second die stack structure 302. A signal line 41 in the second substrate 40 is connected with the second conductive bumps 32. A third conductive bump 42 is formed on one side, close to the first semiconductor die 20, of the second substrate 40, along the second direction.

Referring first to FIG. 7E, the operation of providing the second substrate 40 includes the following operations. The second substrate 40 is cut, so that a surface, on which the third conductive bump 42 is formed, of the second substrate 40 is flush with a surface, close to the first semiconductor die 20, of the first die stack structure 301, and the signal line 41 is exposed.

Specifically, the first die stack structure 301 and the second die stack structure 302 are first welded to the second substrate 40 through the second conductive bumps 32. The second substrate 40 is then cut to a suitable size, such as to be flush with the surface, close to the first semiconductor die 20, of the first die stack structure 301, and then the remaining second substrate 40′ is then removed.

It should be noted that, in the embodiment shown in FIG. 7E, the surface, on which the third conductive bump 42 is formed, of the second substrate 40 is flush with the surface, close to the first semiconductor die 20, of the first die stack structure 301. In an embodiment in which the semiconductor package structure as shown in FIG. 2 is formed, the surface, on which the third conductive bump 42 is formed, of the second substrate 40 is flush with the surface, on which the first conductive bump 21 is formed, of the first semiconductor die 20.

Next referring to FIG. 7F, third conductive bumps 42 are formed on the surface, exposing the signal line 41, of the cut second substrate 40, and the third conductive bumps 42 are connected with the signal line 41.

In some embodiments, the signal line 41 includes a ground line 411 and a power line 412, and the second conductive bumps 32 include first sub-conductive bumps 321 and second sub-conductive bumps 322. The ground line 411 is electrically connected with the first sub-conductive bump 321 and the power line 412 is electrically connected with the second sub-conductive bump 322.

In some embodiments, the ground signal of the second semiconductor die stack structure is led out to the ground line 411 through the first sub-conductive bump 321. The power signal of the second semiconductor die stack structure is led out to the power line 412 through the second sub-conductive bump 322. Then the ground line 411 and the power line 412 are electrically connected with the first substrate 10 through the third conductive bump 42. Therefore, the first substrate 10 supplies power to the second semiconductor die stack structure through the third conductive bump 42, the ground line 411 and the power line 412.

FIG. 5 is a side view along the first direction of the second conductive bump provided by an embodiment of the present disclosure.

As shown in FIG. 5, two adjacent second sub-conductive bumps 322 are at least spaced by one first sub-conductive bump 321, and the second sub-conductive bumps 322 are surrounded by first sub-conductive bumps 321.

P (Power) in the FIG. 5 represents the second sub-conductive bump 322 and G (Ground) in the FIG. 5 represents the first sub-conductive bump 321.

The second sub-conductive bumps 322 are completely surrounded by the first sub-conductive bumps 321, and since the first sub-conductive bump 321 is connected with the ground signal and the second sub-conductive bump 322 is connected with the power signal, crosstalk between different power signals can be reduced and shielding of the power supply can be enhanced.

Next referring to FIG. 7G, a first substrate 10 is provided. The first semiconductor die 20 is connected with the first substrate 10 through the first conductive bumps 21, and the second substrate 40 is connected with the first substrate 10 through the third conductive bumps 42.

With continued reference to FIG. 7G, a substrate connecting bump 12 is formed on the lower surface of the first substrate 10. The substrate connecting bump 12 includes conductive material.

In some embodiments, as shown in FIG. 7G, a groove 101 is formed in the first substrate 10, and the first semiconductor die 20 is placed in the groove 101.

In some embodiments, the first semiconductor die is placed in the groove of the first substrate, and the package height of the semiconductor package structure can be reduced.

In other embodiments, as shown in FIG. 2, the first semiconductor die 20 is located on the first substrate 10, and the first conductive bump 21 is located between the first semiconductor die 20 and the first substrate 10.

In some embodiments, the first semiconductor die is located above the first substrate, so that the first substrate does not need to be provided with the groove, so the process is simpler, and there is a gap between the first semiconductor die and the first substrate, which can increase the heat dissipation effect of the first semiconductor die.

The first semiconductor die 20 and the first substrate 10 are electrically connected through the first conductive bump 21. The power is supplied to the first semiconductor die by the first substrate 10 in a wired manner, and signal exchange is performed.

The first conductive bump 21 is further connected with the substrate connecting bump 12 through the lead line 11 in the first substrate 10, so that the first semiconductor die 20 may exchange information with an external device through the substrate connecting bump 12.

The third conductive bump 42 is further connected with the substrate connecting bump 12 through the lead line 11 in the first substrate 10, so that the second semiconductor die stack structure can exchange information with the external device through the substrate connecting bump 12.

Next, referring to FIG. 7H, the method further includes the following operation. A package compound structure 80 is formed on the first substrate 10. The package compound structure 80 at least wraps the second semiconductor die stack structure and the second substrate 40.

In some embodiments shown in FIG. 2, the package compound structure 80 further wraps the first semiconductor die 20.

The package compound structure 80 includes a silicon-containing compound. The silicon-containing compound may be a spin on glass coating (SOG), a silicon-containing Spin on Dielectric (SOD), or other silicon-containing spin coating material.

The package compound structure 80 is formed and the material of the package compound structure 80 includes a silicon-containing compound, so that the warping problem of the second semiconductor die stack structure can be reduced.

Next, the method further includes the following operation. A filling layer 70 is formed. The filling layer 70 is located between the second semiconductor die stack structure and the second substrate 40, and/or, located between the first semiconductor die 20 and the first substrate 10.

In some embodiments, the filling layer 70 may further be located between the second substrate 40 and the first substrate 10.

For example, in some embodiments, as shown in FIG. 7H, when the first semiconductor die 20 is located in the groove of the first substrate 10, the filling layer 70 may be located between the second semiconductor die stack structure and the second substrate 40, and/or located between the second substrate 40 and the first substrate 10.

In some other embodiments, as shown in FIG. 2, when the first semiconductor die 20 is located above the first substrate 10, the filling layer 70 may be located between the first semiconductor die 20 and the first substrate 10, and/or located between the second semiconductor die stack structure and the second substrate 40, and/or located between the second substrate 40 and the first substrate 10.

For a 3D stacked second semiconductor die stack structure, the warping degree of the second semiconductor die stack structure is high since the thickness along the first direction is thin. When the second semiconductor die stack structure is erected on the first semiconductor die, it is difficult to weld between the second semiconductor die stack structure and the second substrate because of the high warping degree. Therefore, a filling layer is provided between the second semiconductor die stack structure and the second substrate, and between the first substrate and the first semiconductor die, which can effectively reduce the impact caused by the mismatch of the overall temperature expansion characteristics between the die and the substrate or the external force, and increase the reliability of the semiconductor package structure.

In some embodiments, the material of the filling layer 70 includes Epoxy.

Epoxy may be coated on the edge of the die by capillary action principle, so that it can penetrate into the bottom of the die or substrate, and then be cured by heating. Because Epoxy can effectively improve the mechanical strength of solder joints, the service life of the die is prolonged.

In some embodiments, the Young's modulus of the filling layer 70 is greater than the Young's modulus of the package compound structure 80.

Young's modulus is a physical quantity that can describe the ability of solid materials to resist deformation. If the Young's modulus is greater, the ability to resist deformation is greater. When Young's modulus is too low, it will be difficult to maintain the rigidity of the package structure, and it is easy to cause issues such as deformation, warping or damage, etc. Therefore, in the embodiments of the present disclosure, the filling layer is formed, and the Young's modulus of the filling layer is greater than the Young's modulus of the package compound structure, so that the filling layer can have sufficient strength to support the whole package structure, and the package structure is not prone to deformation, warping, damage and the like.

The above is only preferred embodiments of the disclosure and not intended to limit the protection scope of the disclosure. Any modifications, equivalent replacements, improvements and the like made within the spirit and principle of the disclosure shall fall within the protection scope of the disclosure.

1. A semiconductor package structure, comprising:
a first semiconductor die, wherein a first wireless communication portion is formed in the first semiconductor die; and
a second semiconductor die stack structure, wherein the second semiconductor die stack structure comprises a first die stack structure located on the first semiconductor die and a second die stack structure located on the first die stack structure, the second semiconductor die stack structure comprises a plurality of second semiconductor dies stacked in sequence along a first direction, a second wireless communication portion and a third wireless communication portion are respectively formed in two sides, along a second direction, of the first die stack structure, a fourth wireless communication portion is formed in one side, opposite to the first die stack structure, of the second die stack structure, the first direction is a direction parallel to a plane of the first semiconductor die, and the second direction is a direction perpendicular to the plane of the first semiconductor die,
wherein the first wireless communication portion in the first semiconductor die is correspondingly disposed with the second wireless communication portion in the first die stack structure, and the third wireless communication portion in the first die stack structure is correspondingly disposed with the fourth wireless communication portion in the second die stack structure.

2. The semiconductor package structure of claim 1, wherein,
a plurality of second conductive bumps are formed in one side, along the first direction, of the second semiconductor die stack structure,
the semiconductor package structure further comprises:
a first substrate, wherein the first semiconductor die is connected with the first substrate through a first conductive bump,
a second substrate, wherein a signal line in the second substrate is connected with the plurality of second conductive bumps, a third conductive bump is formed on one side, close to the first substrate, of the second substrate, along the second direction, and the second substrate is connected with the first substrate through the third conductive bump.

3. The semiconductor package structure of claim 1, wherein,
the first wireless communication portion comprises a plurality of first sub-portions, first sub-portions of the plurality of first sub-portions are disposed along a third direction in the first semiconductor die, wherein the third direction is a direction parallel to the plane of the first semiconductor die and forms an included angle with the first direction, and the included angle is greater than 25° and less than 65°.

4. The semiconductor package structure of claim 1, wherein,
the second wireless communication portion comprises a plurality of second sub-portions, the third wireless communication portion comprises a plurality of third sub-portions, and the fourth wireless communication portion comprises a plurality of fourth sub-portions, at least one second sub-portion and at least one third sub-portion are comprised in each of second semiconductor dies in the first die stack structure, and at least one fourth sub-portion is comprised in each of second semiconductor dies in the second die stack structure.

5. The semiconductor package structure of claim 1, wherein,
the second semiconductor die stack structure comprises N first die stack structures stacked along the second direction, wherein N is an integer greater than or equal to 1.

6. The semiconductor package structure of claim 1, wherein,
the first semiconductor die comprises a logic die, and the second semiconductor die stack structure comprises a Dynamic Random Access Memory (DRAM) die.

7. The semiconductor package structure of claim 1, further comprising:
an adhesive film located between the first semiconductor die and the second semiconductor die stack structure.

8. The semiconductor package structure of claim 2, wherein,
a groove is formed in the first substrate, and the first semiconductor die is located in the groove.

9. The semiconductor package structure of claim 2, wherein,
the first semiconductor die is located on the first substrate, and the first conductive bump is located between the first semiconductor die and the first substrate.

10. The semiconductor package structure of claim 1, further comprising:
a plurality of Through Silicon Vias (TSVs) penetrating, along the first direction, the second semiconductor dies; and
a plurality of fourth conductive bumps located between two adjacent second semiconductor dies and connected with the TSVs correspondingly.

11. The semiconductor package structure of claim 2, wherein,
the signal line comprises a ground line and a power line, and the plurality of second conductive bumps comprises first sub-conductive bumps and second sub-conductive bumps; and
the ground line is electrically connected with the first sub-conductive bumps, and the power line is electrically connected with the second sub-conductive bumps.

12. The semiconductor package structure of claim 11, wherein,
two adjacent second sub-conductive bumps are at least spaced by one first sub-conductive bump, and the second sub-conductive bumps are surrounded by first sub-conductive bumps.

13. The semiconductor package structure of claim 2, wherein the semiconductor package structure further comprises at least one of the following:
a filling layer located between the second semiconductor die stack structure and the second substrate, or, a filling layer located between the first semiconductor die and the first substrate.

14. A method for manufacturing a semiconductor package structure, comprising:
forming a first die stack structure, wherein the first die stack structure comprises a plurality of second semiconductor dies stacked in sequence along a first direction;
forming a second wireless communication portion and a third wireless communication portion in two sides, along a second direction, of the first die stack structure respectively;
forming a first semiconductor die;
forming a first wireless communication portion in the first semiconductor die;
placing a surface, on which a second wireless communication portion is formed, of the first die stack structure on the first semiconductor die;
forming a second die stack structure, the second die stack structure comprising a plurality of second semiconductor dies stacked in sequence along the first direction;
forming a fourth wireless communication portion in one side, along the second direction, of the second die stack structure; and
placing a side surface, on which the fourth wireless communication portion is formed, of the second die stack structure on the first die stack structure, wherein the first direction is a direction parallel to a plane of the first semiconductor die, and the second direction is a direction perpendicular to the plane of the first semiconductor die,
wherein the first wireless communication portion in the first semiconductor die is correspondingly disposed with the second wireless communication portion in the first die stack structure, and the third wireless communication portion in the first die stack structure is correspondingly disposed with the fourth wireless communication portion in the second die stack structure.

15. The method of claim 14, further comprising:
forming a first conductive bump on one side surface, away from the first die stack structure, of the first semiconductor die;
forming a plurality of second conductive bumps on one side, along the first direction, of the first die stack structure and the second die stack structure;
providing a second substrate after forming the second die stack structure, wherein a signal line in the second substrate is connected with the plurality of second conductive bumps;
forming, along the second direction, a third conductive bump on one side, close to the first semiconductor die, of the second substrate;
providing a first substrate;
connecting the first semiconductor die with the first substrate through the first conductive bump; and
connecting the second substrate with the first substrate through the third conductive bump.
